(19) United States
(12) Patent Application Publication
(10) Pub. No.: US 2003/0122480 A1
(43) Pub. Date: Jul. 3, 2003

(54) Organic flat light-emitting device

(76) Inventors: Mao-Kuo Wei, Hsinchu (TW); Jih-Yi Wang, Hsinchu (TW)

Correspondence Address: BIRCH STEWART KOLASCH & BIRCH, PO BOX 747, FALLS CHURCH, VA, 22040-0747, US

(21) Appl. No.: 10/310,047

(22) Filed: Dec. 5, 2002

(30) Foreign Application Priority Data
Dec. 31, 2001 (TW) 090133403

(51) Int. Cl. H05B 33/00

(52) U.S. Cl. 313/506

(57) ABSTRACT

An organic flat light-emitting device. The device includes a transparent substrate, a transparent anode, at least one organic electro-luminescent layer, and a metal cathode. In this case, a first surface of the transparent substrate has several microstructures, and each of the microstructures has a maximum height of 100 μm. The transparent anode is formed on a second surface of the transparent substrate that is opposite to the first surface. The organic electro-luminescent layer is formed on the transparent anode. The metal cathode is formed on the organic electro-luminescent layer. Furthermore, the invention also discloses another organic flat light-emitting device, which includes a transparent substrate, a transparent thin film, a transparent anode, at least one organic electro-luminescent layer, and a metal cathode. The transparent thin film is formed on a first surface of the transparent substrate. The transparent thin film has a plurality of microstructures, each of which has a maximum height of 100 μm. The transparent anode is formed on a second surface of the transparent substrate opposite to the first surface. The organic electro-luminescent layer is formed on the transparent anode. The metal cathode is formed on the organic electro-luminescent layer.

### BACKGROUND OF THE INVENTION

1. Field of Invention

The invention relates to an organic flat light-emitting device and, in particular, to an organic flat light-emitting device that has microstructures.

2. Related Art

Referring to FIG. 1, an organic light-emitting device 3 includes a transparent substrate 31, a transparent anode 32, an organic electro-luminescent layer 33, and a metal cathode 34. Due to the metal cathode 34 being a reflecting layer, the light emitted from the organic electro-luminescent layer 33 can only pass through the transparent substrate 31.

In organic flat light-emitting devices, the refraction index of the organic electro-luminescent layer 33 n₁ (≈1.7) is very close to that of the transparent anode 32 n₂ (≈1.8-2.0), and the refraction index of the transparent substrate 31 n₃ (≈1.4-1.5) is smaller than n₁ and larger than that of air (≈1). According to Snell's Law, when a beam of light goes through an interface, the product of the refraction index and the sine of the incident angle in the incident medium are equal to that in the refractive medium. When a beam of light goes from the transparent anode 32 into the transparent substrate 31 and the incident angle is greater than sin⁻¹(n₃/n₂), total reflection occurs and the light is limited to propagation within the organic electro-luminescent layer 33 and the transparent anode 32. This results in the transparent anode 32/organic electro-luminescent layer 33 waveguide phenomenon. If the beam of light propagates out from the transparent substrate 31 and the incident angle is greater than sin⁻¹(1/n₃), the light will be totally reflected. The light is restricted to propagation within the transparent substrate 31, resulting in the substrate waveguide phenomenon. However, when the incident angle is smaller than sin⁻¹(1/n₃), light will propagate out of the element. One thus sees that only part of the light generated by the organic flat light-emitting device 3 that can propagate out of the element. The rest results in the substrate waveguide phenomenon inside the substrate. Therefore, the light flux emitted from the organic flat light-emitting device 3 is obviously less than that generated by the organic electro-luminescent layer 33.

The conventional manufacturing method of organic flat light-emitting devices often uses a substrate with a high refraction index and attaches convex lenses on the light-emitting surface to increase the external quantum efficiency. As shown in FIG. 2, convex lenses 41 with a diameter between 2 mm and 3 mm are attached on the light-emitting surface of a device 4. If the material of the convex lenses 41 is the same as that of the transparent substrate of the light-emitting element 42, the light flux of the light-emitting element can be increased by 60% to 100%. If lenses with a higher refraction index are used, the light flux of the element can be increased by 200%. When making the light-emitting element 4, a refraction index matching oil is employed to attach the convex lenses 41 to the light-emitting surface. This is not suitable for long-term use. Another commonly used technique is that disclosed in the U.S. Pat. Nos. 5,936,347 and 6,080,030. The semi-convex lenses or semi-concave lenses are directly formed on a glass substrate by hot-embossing method, thereby increasing the external quantum efficiency of the element. However, the operation temperature for glass hot-embossing method is very high and is likely to make the glass locally deformed. Furthermore, the operation time (for increases and decreases in temperature) is too lengthy for use in mass production.

The lens used in the above-mentioned prior art have the drawbacks of being too thick (millimeter scales) and having large diameter. It is not suitable for the trend of developing compact light-emitting devices. Moreover, the mentioned element cannot be operated for a long time, and the product yields in the prior art are not reliable for commercialization.

### SUMMARY OF THE INVENTION

It is an objective of the invention to provide an organic flat light-emitting device to simplify the processes of manufacturing, to lower the manufacturing cost, to have a compact and light structure, and to have a better light-emitting efficiency.

To achieve the above objective, the organic flat light-emitting device includes a transparent substrate, a transparent anode, at least one organic electro-luminescent layer, and a metal cathode. In this invention, several microstructures are formed on a first surface of the transparent substrate, wherein each of the microstructures has a maximum height of 100 μm. The transparent anode is formed on a second surface of the transparent substrate opposite to the first surface. The organic electro-luminescent layer is formed on the transparent anode. The metal cathode is formed on the organic electro-luminescent layer.

The invention also provides another organic flat light-emitting device, which includes a transparent substrate, a transparent thin film, a transparent anode, at least one organic electro-luminescent layer, and a metal cathode. The transparent thin film is formed on a first surface of the transparent substrate. The transparent thin film has a plurality of microstructures, each of which has a maximum height of 100 μm. The transparent anode is formed on a second surface of the transparent substrate opposite to the first surface. The organic electro-luminescent layer is formed on the transparent anode. The metal cathode is formed on the organic electro-luminescent layer.

According to this invention, the organic flat light-emitting device has several microstructures to increase the external quantum efficiency of the element. It can achieve the goals of saving energy and being environmentally friendly. Moreover, this invention combines the microstructures and the transparent substrate, so that the manufacturing processes of the device is simplified and the manufacturing time can be shortened, and the cost can be lowered. The thickness of the substrate and the whole device can be minimized so as to achieve the requirement for compact electric products. Furthermore, the organic flat light-emitting device according this invention is suitable for long-term use. The glass substrate is not necessary, so that the partial warps of the substrate can be avoided during the manufacturing.

### BRIEF DESCRIPTION OF THE DRAWINGS

The invention will become more fully understood from the detailed description given in the herein below illustration, and thus are not limitative of the present invention, and wherein:

FIG. 1 is a schematic view of the conventional organic flat light-emitting device;

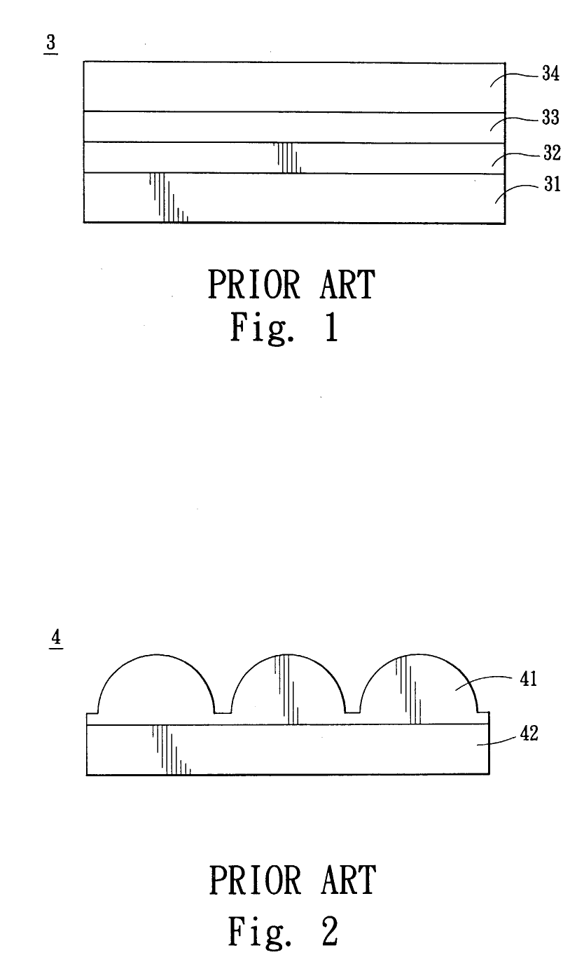

FIG. 2 is a schematic view of the conventional transparent substrate;

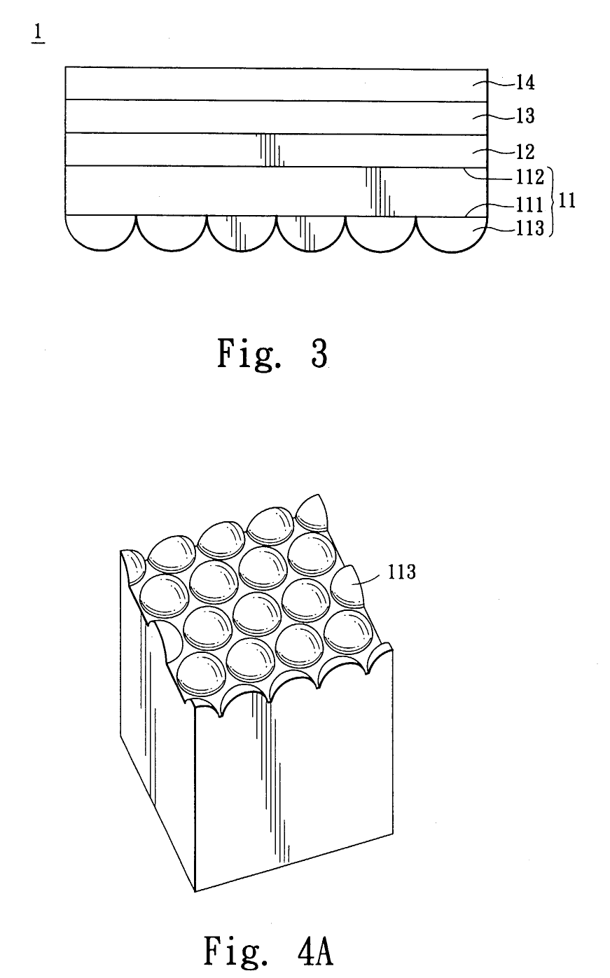

FIG. 3 is a schematic view of an embodiment of the disclosed organic flat light-emitting device;

FIGS. 4A to 4C are schematic views of the microscopes of the invention; and

FIG. 5 is a schematic view of another embodiment of the disclosed organic flat light-emitting device.

### DETAILED DESCRIPTION OF THE INVENTION

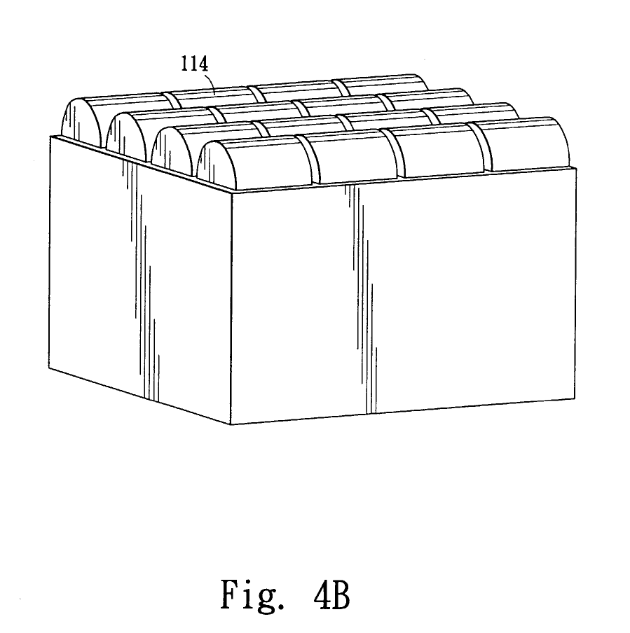

As shown in FIG. 3, an embodiment of an organic flat light-emitting device 1 includes a transparent substrate 11, a transparent anode 12, at least an organic electro-luminescent layer 13, and a metal cathode 14. In this embodiment, a first surface 111 of the transparent substrate 11 has several microstructures 113, and the maximum distance from the top of each microstructure 113 to the first surface 111 is about 100 μm. The transparent anode 12 is formed on a second surface 112 of the transparent substrate 11 opposite to the first surface 111. The organic electro-luminescent layer 13 is formed on the transparent anode 12. The metal cathode 14 is formed on the organic electro-luminescent layer 13.

The transparent substrate 11 may be a plastic substrate or a flexible substrate. In this case, the plastic substrate or the flexible substrate may be a polycarbonate (PC) substrate, a polyester (PET) substrate, a cyclic olefin copolymer (COC) substrate, or a metallocene-based cyclic olefin copolymer (mCOC). The thickness of the transparent substrate 11 is between 0.2 mm and 5 mm.

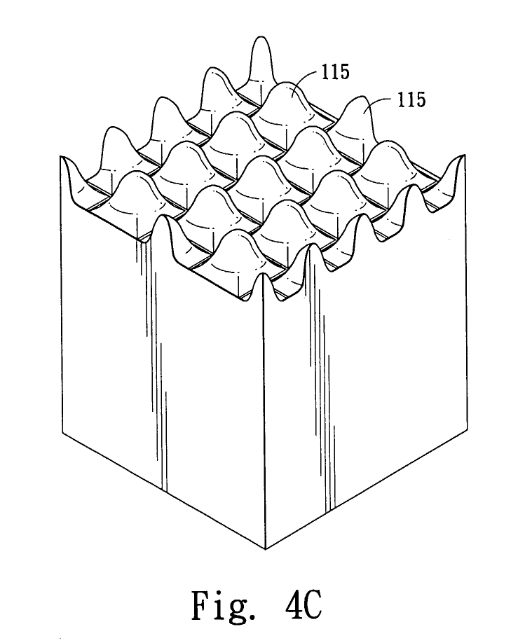

As shown in FIG. 3, the first surface 111 of the transparent substrate 11 has several microstructures 113. The distance from the top of each microstructure 113 to the first surface 111 is between 5 μm and 100 μm. Here, each of the microstructures 113 has a curved surface. The surface may be like a spherical cap (as shown in FIG. 4A). The diameter of the base of the spherical cap is between 10 μm and 500 μm. Certainly, the microstructures 113 can also be cylindrical caps 114 (as shown in FIG. 4B). The cylindrical cap 114 has a diameter between 10 μm and 500 μm and a length between 10 μm and 500 μm. Moreover, the microstructures 113 may be a protruding curved surface with a regular polygon border 115. An example with a square border is shown in FIG. 4C. The perimeter of the square border of the protruding curved surface 115 is between 10 μm and 500 μm.

The microstructures 113 in the embodiment are used to enhance the external quantum efficiency of the organic flat light-emitting device 1. In the light-emitting device 1, the refraction index of the transparent substrate 11 n_{sub} is greater than that of air. Therefore, when the incident angle of a beam of light produced inside the element is greater than a threshold angle sin⁻¹(1/n_{sub}) at the transparent substrate 11/air interface, it will be totally reflected, resulting in the substrate waveguide phenomenon. The microstructures 113 in the embodiment converge light beams with incident angles greater than the threshold angle and guide them out of the element. This is why the invention can greatly increase the external quantum efficiency of the organic flat light-emitting device 1.

In the current embodiment, the transparent substrate 11 can be formed by injection molding method. Two molds (not shown) are used in the injection molding method. The surface of the first mold is an optics-graded smooth plane. The surface of the second mold has microscope structures. After being heated and melted, plastic particles are ejected between the two molds to make a transparent substrate II with the microstructures.

On the other hand, the transparent substrate II can be formed by hot-embossing method. This method requires an optics-graded platform (now shown). The transparent substrate 11 is placed on to the platform and heated to a working temperature. The hot embossing mold is placed on the transparent plastic substrate and imposed by a homogeneous pressure. The hot embossing mold has microstructures to form the transparent substrate 11 with microstructures.

The second surface 112 of the transparent substrate 11 is an optics-graded smooth plane without any geometric structure. The transparent anode 12 is formed on the second surface 112 by method of sputtering or ion plating. The transparent anode 12 can be made of a conductive metal oxide such as indium-tin oxide (ITO) or aluminum-zinc oxide (AZO). The thickness of the transparent anode 12 is above 500 Å.

Afterwards, at lease one organic electro-luminescent layer 13 is formed on the transparent anode 12 by evaporation, spin coating, ink jet printing or printing. Its thickness is between 500 Å and 3000 Å. The light emitted by the organic electro-luminescent layer 13 may be blue, green, red, other monochrome or white light. It should be noticed that the organic electro-luminescent layer 13 could be a multi-layer structure.

The metal cathode 14 is formed on the organic electro-luminescent layer 13 by method of evaporation or sputtering. Its thickness is between 500 Å and 5000 Å. In the current embodiment, the metal cathode 14 is made of aluminum, aluminum/lithium fluoride, calcium, magnesium-silver alloys or silver.

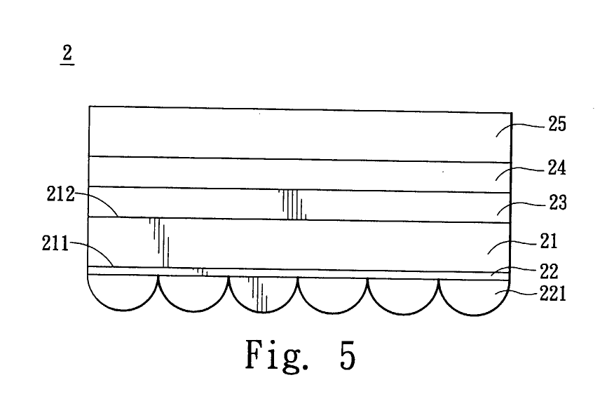

As shown in FIG. 5, in another embodiment of the invention, an organic flat light-emitting device 2 includes a transparent substrate 21, a transparent thin film 22, a transparent anode 23, at least one organic electro-luminescent layer 24, and a metal cathode 25. The transparent thin film 22 is formed on a first surface 211 of the transparent substrate 21. The transparent thin film 22 has several microstructures 221 with a maximal height of 100 μm. A second surface 212 of the transparent substrate 21 opposite to the first surface 211 is formed with the transparent anode 23. The transparent anode 23 is formed with the organic electro-luminescent layer 24. The metal cathode 25 is formed on the organic electro-luminescent layer 24.

In this case, the transparent substrate 21 may be a plastic substrate, a flexible substrate, or a glass substrate. The plastic substrate and the flexible substrate may be a polycarbonate (PC) substrate, a polyester (PET) substrate, a cyclic olefin copolymer (COC) substrate, or a metallocene-based cyclic olefin copolymer (mCOC). The thickness of the transparent substrate 21 is between 0.2 mm and 5 mm.

The transparent thin film 22 is formed on the first surface 211 of the transparent substrate 21 by an adhesive method. The adhesive method is to use thermal cured glue or UV cured glue to attach the transparent thin film 22 on the transparent substrate 21. The surface of the transparent thin film 22 has several microstructures 221. The height of each microstructure 221 is between 5 μm and 100 μm. In the current embodiment, the features and functions of the microstructures 221 are the same as those in the first embodiment. Other elements in the current embodiment also have the same features and functions as those in the first embodiment.

The disclosed organic flat light-emitting device according to this invention has special microstructures. In the provided embodiments, the function of the microstructures is to efficiently transmit light generated by the organic electro-luminescent layer out of the element, increasing the external quantum efficiency of the organic flat light-emitting device. In comparison with the prior art, the disclosed device has strongly reduced manufacturing time and lowered cost. The microstructures can effectively reduce the thickness of the device.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A organic flat light-emitting device, comprising:
a transparent substrate, which has a first surface and a second surface opposite to the first surface, the first surface being formed with a plurality of microstructures and each of the microstructures having a maximal height of 100 μm;
a transparent anode, which is formed on the second surface of the transparent substrate;
at least one organic electro-luminescent layer, which is formed on the transparent anode; and
a metal cathode, which is formed on the organic electro-luminescent layer.

2. The device of claim 1, wherein the transparent substrate is a plastic substrate.

3. The device of claim 1, wherein the transparent substrate is a flexible substrate.

4. The device of claim 1, wherein the transparent substrate is formed by injection molding method.

5. The device of claim 1, wherein the transparent substrate is formed by hot-embossing method.

6. The device of claim 1, wherein the thickness of the transparent substrate is between 0.2 mm and 5 mm.

7. The device of claim 1, wherein the height of each microstructure is about 5 μm to 100 μm.

8. The device of claim 1, wherein the microstructures have a curved surface.

9. The device of claim 8, wherein the curved surface has a spherical shape with a diameter between 10 μm and 500 μm.

10. The device of claim 8, wherein the curved surface has a cylindrical shape with a diameter between 10 μm and 500 μm and a length between 10 μm and 500 μm.

11. The device of claim 8, wherein the curved surface is a protruding surface having a regular polygon border with a perimeter between 10 μm and 500 μm.

12. A organic flat light-emitting device, comprising:
a transparent substrate;
a transparent thin film, which is formed on a first surface of the transparent substrate, the transparent thin film having a plurality of microstructures and each of the microstructures having a maximal height of 100 μm;
a transparent anode, which is formed on a second surface of the transparent substrate opposite to the first surface;
at least one organic electro-luminescent layer, which is formed on the transparent anode; and
a metal cathode, which is formed on the organic electro-luminescent layer.

13. The device of claim 12, wherein the transparent substrate is a plastic substrate.

14. The device of claim 12, wherein the transparent substrate is a flexible substrate.

15. The device of claim 12, wherein the transparent substrate is a glass substrate.

16. The device of claim 12, wherein the thickness of the transparent substrate is between 0.2 mm and 5 mm.

17. The device of claim 12, wherein the transparent thin film is formed on the first surface by an adhesive method.

18. The device of claim 12, wherein the microstructures have a curved surface.

19. The device of claim 18, wherein the curved surface has a spherical shape with a diameter between 10 μm and 500 μm.

20. The device of claim 18, wherein the curved surface has a cylindrical shape with a diameter between 10 μm and 500 μm and a length between 10 μm and 500 μm.

21. The device of claim 18, wherein the curved surface is a protruding surface having a regular polygon border with a perimeter between 10 μm and 500 μm.
